(19) United States
(12) Patent Application Publication
(10) Pub. No.: US 2010/0039107 A1
(43) Pub. Date: Feb. 18, 2010

(54) MAGNETIC CARRIER MANIPULATION AND DETECTION USING A NANOMETER SCALE TRANSFORMER

(75) Inventors: Doyeol AHN, Seoul (KR); Hyung Kwon Kim, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: UNIVERSITY OF SEOUL INDUSTRY COOPERATION FOUNDATION, Seoul (KR)

(21) Appl. No.: 12/192,037

(22) Filed: Aug. 14, 2008

(51) Int. Cl. H01F 38/20; G01R 33/02

(52) U.S. Cl. 324/258; 336/173

(57) ABSTRACT

A nanometer scale transformer configured to manipulate and detect a magnetic carrier is provided.

### BACKGROUND

Magnetic carriers, including but not limited to microspheres, microbeads, and nano-particles, have been the center of attention in a wide spectrum of applications because a labeled magnetic particle can provide binding between a receptor and a target molecule attached to the labeled particle. The binding ability makes various applications practical including, by way of example and not by limitation, magnetic bio-molecular separation, magnetic resonance imaging, drug delivery, and immunoassay. However, the magnetic carrier by itself does not lead to desirable consequences for each specific application, and thus, it is necessary to have a tool that is able to detect or manipulate the magnetic particle. In this regard, it is very important to sense a very weak magnetic field from the magnetic carrier.

Many various types of prior art magnetic sensing devices have been proposed to detect magnetic carriers. Some of these prior art devices include giant magnetoresistive (GMR) sensors, superconducting quantum interference devices (SQUIDs), spin valve sensors, anisotropic magnetoresistive (AMR) sensors, Hall sensors, and micro-cantilever sensors. However, most of the prior art devices require complex fabrication processes, such as multi-layered metal formation and etching, and need a special kind of substrate such as a hetero-junction substrate. In this regard, the prior art devices have not been fully satisfactory in terms of their reliability, accuracy, and cost-effectiveness.

### BRIEF DESCRIPTION OF THE DRAWINGS

FIG. 1 shows an illustrative embodiment of a scanning electron microscopy (SEM) image of a nanometer scale transformer.

FIG. 2 shows a schematic diagram of an illustrative embodiment of a micro array of nanometer scale transformers.

FIG. 3 shows a schematic diagram of an illustrative embodiment of a device configured to manipulate or detect magnetic carriers.

FIG. 4 is a flowchart of an illustrative embodiment of a method for manipulating magnetic carriers.

FIG. 5 shows an illustrative embodiment of scanning electron microscopy (SEM) images of magnetic beads positioned around the center of the nanometer scale transformer.

FIG. 6 is a flowchart of an illustrative embodiment of a method for detecting magnetic carriers.

FIG. 7(a) shows an illustrative embodiment of a graph illustrating the dependency of the EMF outputs on the input current frequency (f) without magnetic beads on the nanometer scale transformer.

FIG. 7(b) shows an illustrative embodiment of a graph illustrating the dependency of the EMF outputs on the input current frequency (f) with magnetic beads on the nanometer scale transformer.

FIG. 8(a) shows an illustrative embodiment of a graph illustrating the differences in the EMF output responses of the nanometer scale transformer having beads and the nanometer scale transformer having no beads as the current frequency changes.

FIG. 8(b) shows an illustrative embodiment of a graph illustrating the differences in the EMF output responses of the nanometer scale transformer having beads and the nanometer scale transformer having no beads as the current magnitude changes.

FIG. 9 shows a schematic diagram of an illustrative embodiment of a representative cross-section view of the magnetic bead on the nanometer scale transformer.

### DETAILED DESCRIPTION

In the following detailed description, reference is made to the accompanying drawings, which form a part hereof In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

In one aspect, the disclosure relates to providing a nanometer scale transformer. As disclosed herein, the nanometer scale transformer can be fabricated as any suitable structure to cause electromagnetic induction in nano-scale range. The electromagnetic induction is well known as Faraday's law in the macroscopic domain and has been involved in many applications in macroscopic electromagnetism, such as radio antenna, induction stove, transformers, and electric generator. In the following, the disclosure shows that the nanometer scale transformer having various geometric dimensions may cause the Faraday's law induction, where the change of the magnetic flux through a circuit can induce the electromotive force (EMF). The nanometer scale transformer of the disclosure comprises a first circuit, a second circuit, and a coupling area for magnetic induction.

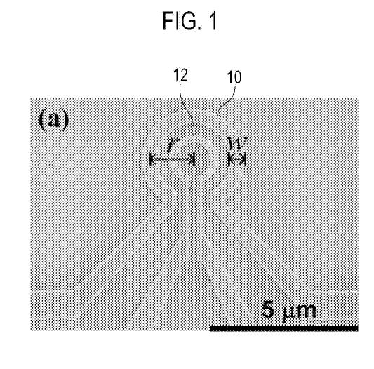

FIG. 1 shows an illustrative embodiment of a scanning electron microscopy (SEM) image of a nanometer scale transformer. The nanometer scale transformer may be fabricated, by way of example only, by using electron beam lithography and lift-off process on a SiO₂ substrate. As will be understood by those skilled in the art, various processes, including but not limited to chemical vapor deposition (CVD), sputter deposition, spin coating, atomic layer deposition (ALD) and the like could be adopted to fabricate the nanometer scale transformer of the disclosure. As shown by way of example, the nanometer scale transformer may include two rings 10 and 12, and the two rings have a predetermined radii (r) and widths (w). Each ring may correspond to a first or a second circuit of the nanometer scale transformer, and the area inside the inner ring may serve to cause magnetic induction. For example, the radius and the width of the inner ring are 300 and 100 nm, respectively, and the radius and the width of the outer ring are 700 and 200 nm, respectively. Alternatively, the inner ring may have a 700 nm radius and a 200 nm width, and the outer ring may have a 1400 nm radius and a 500 nm radius. Furthermore, the two rings may or may not be concentric. The two rings may be made of various materials, including but not limited to Ti, Au, and the like. In other embodiments, the nanometer scale transformer may have other suitable shapes of structures, including but not limited to oval, triangular, rectangular, polygon or square so long as the structure provides sufficient area for magnetic induction coupling in view of nano-scale.

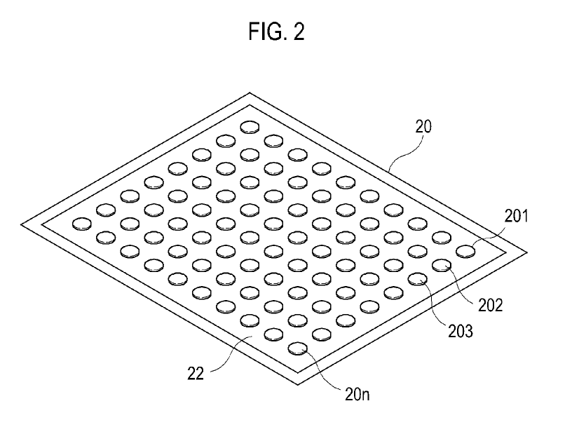

FIG. 2 shows a schematic diagram of an illustrative embodiment of a micro array 20 integrating the nanometer scale transformers. By way of example and not a limitation, the micro array 20 comprises a solid platform 22 and hundreds or thousands of microscopic spots 201, 202, 203, and 20n. In each of the microscopic spots, a nanometer scale transformer according to the disclosure may be fabricated using different process technologies. The process technology may be selected taking into account, among others, the number of necessary nanometer scales transformer, costs, the type of investigation at issue, and etc. The relevant technologies include for example, not limited to, fine printing method, photolithography with predetermined masks, and electrochemistry on microelectrode microarrays. The micro array can lead to more reliable experiment results on a statistical basis because each spot of the array can be considered as one experiment simultaneously conducted under substantially identical experimental conditions. The micro array installed with the nanometer scale transformers may be used for medical diagnosis.

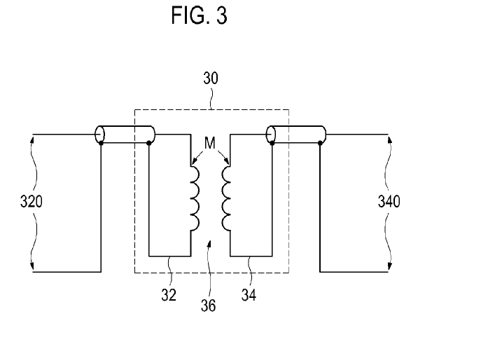

FIG. 3 shows a schematic diagram of an illustrative embodiment of a device with a nanometer scale transformer. The nanometer scale transformer, which is depicted inside a box 30, comprises a first circuit 32, a second circuit 34, and a coupling area 36. The first circuit 32 and the second circuit 34 may be coupled to a first terminal pair 320 and a second terminal pair 340. The first terminal pair 320 and the second terminal pair 340 may, by way of example and not a limitation, be fabricated on a substrate with Au wires and be terminated with a contact pad. Any input including but not limited to an AC current signal and a DC current signal can be applied to either of the first and second terminal pairs 320 and 340. The input is then connected to one of the first and second circuit 32 and 34 of the nanometer scale transformer. The circuit (either the first circuit 32 or the second circuit 34) provided with the input may generate magnetic flux which passes through the coupling area 36. The changes in the magnetic flux at the couple area 36 may induce an EMF output to the other circuit, which is not provided with the input current, in accordance with Faraday's induction law. The EMF can be monitored at the terminal pair connected to the other circuit. In order to detect the EMF, a standard lock-in technique may be adopted. In addition, other than the magnetic coupling between the first circuit 32 and the second circuit 34, wires between the first or second circuit 32 or 34 and the first or second terminal pair 320 or 340 may be carefully designed or shielded to prevent any other non-desirable magnetic coupling from interfering the EMF output.

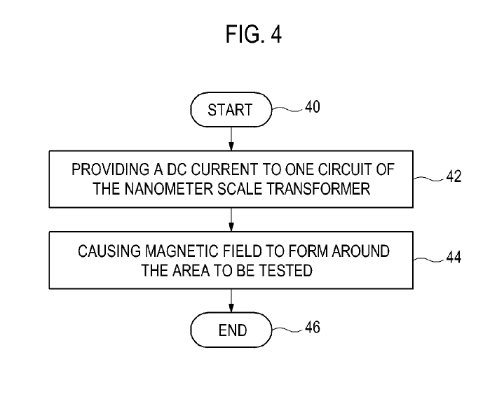

FIG. 4 is a flowchart one of an illustrative embodiment of a method for manipulating magnetic carriers with a nanometer scale transformer. In FIG. 4, the method begins at Block 40. For example, a droplet of the magnetic carrier solution may be dropped on a device with a nanometer scale transformer according to the disclosure. By way of example and not a limitation, the magnetic carriers may be superparamagnetic beads (Dynabeads® MyOne™ Carboxylic Acid), of which the magnetic susceptibility (χ) of the bead is 0.83 and the diameter is 1.05 μm. At Block 42, a DC current is applied to one of the first circuit 32 and the second circuit 34 via its terminal pair. At Block 44, a magnetic field is formed by the DC current supplied to the nanometer scale transformer and is distributed around the area in the vicinity of the nanometer scale transformer. After enough time is given for the magnetic field to affect the magnetic carriers in the solution, the method ends at Block 46.

In one embodiment where the nanometer scale transformer comprises two metal rings which correspond to a first circuit 32 and a second circuit 34 respectively, the DC current of 10 mA may be supplied to the outer ring via the terminal pair connected to the outer ring. Due to the magnetic field formed around the nanometer scale transformer, the magnetic carriers may be captured around the center of the ring. In another embodiment, the magnetic carrier solution may be removed by a weak N₂ blow dry while the DC current is being supplied to the outer ring.

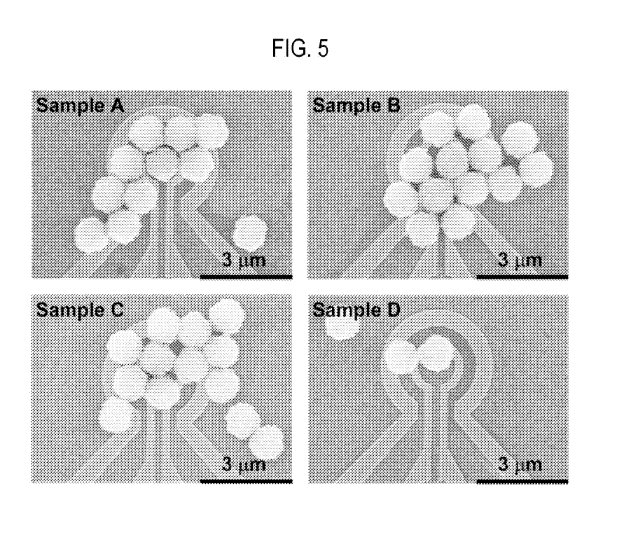

It can be calculated that the magnetic moment of a magnetic carrier is m=VχB/μ₀, and the magnetic force on the carrier is F=∇(m B)=Vχ/μ₀∇B², where m, B, V, χ, and μ₀ are the magnetic moment of the magnetic carrier, the magnetic field, the volume of the carrier, the magnetic susceptibility of the carrier, and the permeability of vacuum, respectively. In order to calculate the strength of the force on the magnetic carriers, the magnetic field simulation may be performed under the following conditions: the nanometer scale transformer comprises two concentric metal rings, of which the inner ring has a 700 nm radius and a 200 nm width, and the outer ring has a 1400 nm radius and a 500 nm width; and the magnetic carrier solution is Dynabeads® MyOne™ Carboxylic Acid. The simulation may also be performed by an electromagnetic field simulator using a finite element method such as, but not limited to, (Maxwell 3D, Ansoft). As the result of the simulation, the gradient of B² around the center of the ring may be about 100 T²/m and the force on a magnetic bead may be approximately 40 pN. This force may be sufficient to drag the magnetic beads to the center of the transformer against the force due to thermal Brownian motion of the beads in solution. The result of the described example simulation may provide a controllable manipulation for the magnetic carrier in accordance with one embodiment. Furthermore, FIG. 5 shows an illustrative embodiment of SEM images showing the above-mentioned conditions. These SEM images further illustrate the capture of the magnetic beads by the nanometer scale transformer in accordance with one embodiment.

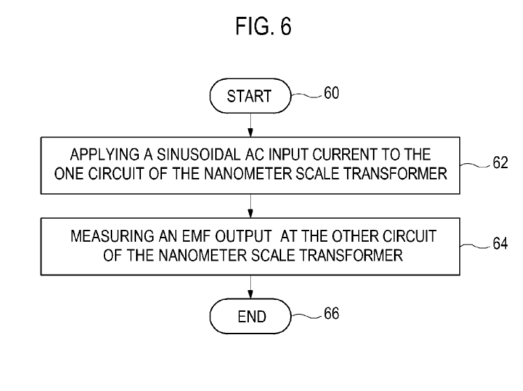

FIG. 6 is a flow chart of an illustrative embodiment of a method for detecting magnetic carriers. The method starts at Block 60 where a device with a nanometer scale transformer may be placed on any stable surface. At Block 62, a sinusoidal AC input current is applied via the one terminal pair to the one circuit (either of the first circuit 32 and the second circuit 34) of the nanometer scale transformer according to the disclosure. Due to the sinusoidal excitement of the input current, a time-varying magnetic flux can be generated around the coupling area of the nanometer scale transformer. Subsequently, by Faraday's law of magnetic induction, the EMF is produced at the other circuit of the nanometer scale transformer. At Block 64, the EMF is measured at the terminal pair connected to the other circuit of the nanometer scale transformer. In a selected embodiment, the measurement may be conducted using a low-noise lock-in amplifier. Finally, the method ends at Block 66.

Here it is possible to determine whether a magnetic carrier is on a nanometer transformer based on the EMF output at the terminal pair. Since the nanometer scale transformer according to the disclosure behaves as a linear transformer, the induced EMF output is supposed to be proportional to the time-varying magnetic flux passing through the coupling area 36 of the nanometer scale transformer. Assuming that there is no magnetic carrier on the nanometer scale transformer, the time-varying magnetic flux is generated at the coupling area 36 only by the sinusoidal AC current supplied to one circuit of the nanometer scale transformer. In case where there is a magnetic carrier on the nanometer scale transformer, however, additional magnetic flux changes can be brought from the magnetic carrier. In one embodiment, a magnetic carrier has a superparamagnetic character, which refers to the feature of materials having no permanent magnetic dipoles when no external magnetic field applies, but showing magnetic dipoles in response to the magnetic field with certain susceptibilities. Therefore, the magnetic carrier on the nanometer scale transformer may be magnetized by the magnetic field from one circuit supplied with the AC current and in turn, produce its magnetic flux around the coupling area 36 of the nanometer scale transformer. Consequently, the magnetic flux from the magnetic carrier on the nanometer scale transformer results in an increase of the EMF output of the nanometer scale transformer.

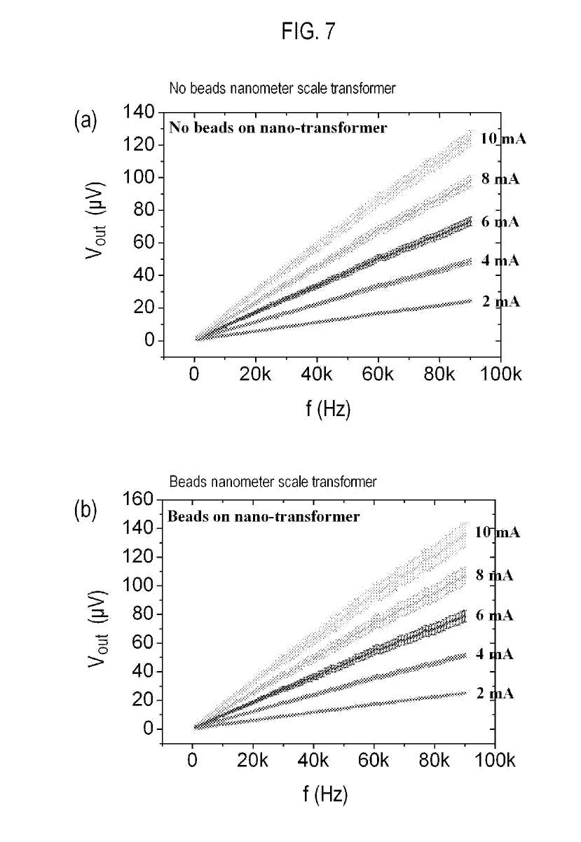

The foregoing will be more evident from the following experimental results. FIGS. 7(a) and 7(b) show the induced EMF outputs out of the experiment using the nanometer scale transformer according to one embodiment of the disclosure. The nanometer scale transformer, as shown in FIG. 1, comprises two metal concentric rings. In this experiment, the radius and the width of the inner ring are 700 and 200 nm, respectively, and the radius and the width of the outer ring are 1400 and 500 nm, respectively. The magnetic carriers used for the experiment are the magnetic beads of the Dynabeads® MyOne™ Carboxylic Acid. A sinusoidal AC input current was applied via the one terminal pair to the outer ring of the nanometer scale transformer and the open-circuited EMF output was measured via the other terminal pair connected to the inner ring by using a low noise lock-in amplifier. The AC input current through the outer ring generates a time-varying magnetic flux through the inner ring, and then the flux causes the EMF at both ends of the inner ring. The input currents were 2 to 10 mA root-mean-square (rms) value with 2 mA steps, and the frequencies were swept from 1 to 90 kHz with 1 kHz steps for each input current.

FIG. 7(a) shows an illustrative embodiment of a graph illustrating the output response as a function of the input current frequency for the nanometer scale transformer without magnetic beads. The filled circle and the error bar represent the average value and the standard deviation of the induced EMF outputs acquired from a number of experiments using different nanometer scale transformers with the same dimension, respectively. The output response is almost linear with the input current frequency and also with the input current magnitude. This indicates that the nanometer scale transformer of the disclosure behaves as a linear transformer. Measuring the open-circuited EMF output at the inner ring, we can extract the mutual inductance of the transformer from the following equation,

V_{out=jωMI}ᵢₙ (1)

where Vₒᵤₜ, ω, M, and Iᵢₙ are the induced EMF output, the angular frequency of the input current, the mutual inductance, and the input current, respectively. The mutual inductance of the transformer without magnetic bead is approximately 22 nH in view of the experimental results shown in FIG. 7(a).

FIG. 7(b) shows an illustrative embodiment of a graph illustrating the EMF output response of the nanometer scale transformer with beads thereon. The EMF outputs also show a linear increase with the frequency of the input current. As shown in FIG. 7(b), when the magnetic beads are on the nanometer scale transformer, the mutual inductance can be calculated to be approximately 24 nH, which is 2 nH larger than that of the transformer without the beads. This indicates that the nanometer scale transformer can be used to detect if the magnetic carrier is on the nanometer scale transformer. As shown by the experiment results in FIGS. 7(a) and 7(b), when the magnetic carrier is on the nanometer scale transformer, the EMF output is larger than when no beads are on the transformer.

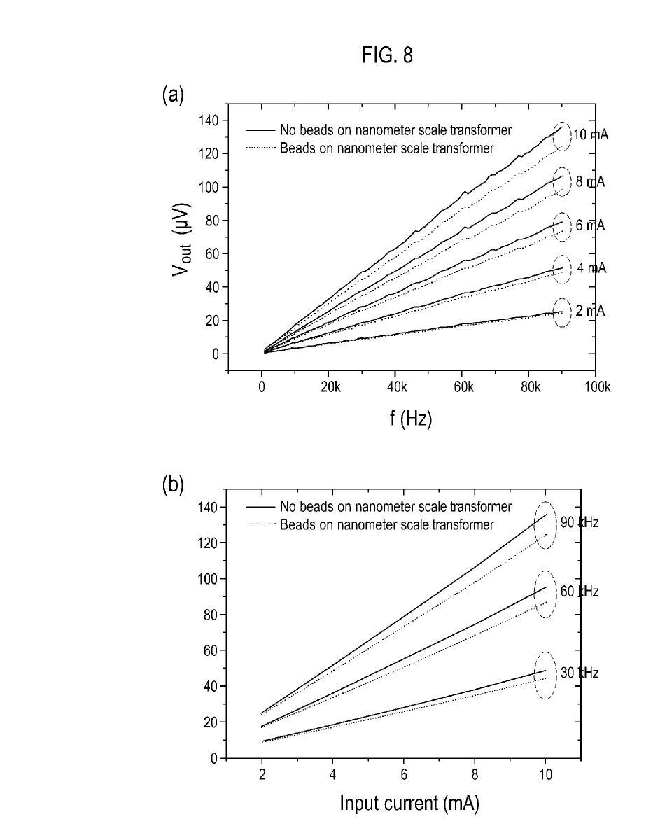

Referring to FIG. 8(a) and 8(b), the above experimental results are illustrated in a way to directly compare the EMF outputs with magnetic beads on the nanometer scale transformer to those with no magnetic beads thereon. FIG. 8(a) shows an illustrative embodiment of a graph illustrating the average EMF outputs as a function of input frequency for each input current. The broken lines and the solid lines denote the EMF output responses of the nanometer scale transformers without and with beads, respectively. The EMF outputs are larger when the magnetic beads are on the transformers as compared with the case of no bead on the transformer. The gap or difference in the output becomes larger as the frequency of the input current increases. As will be shown later, these increments result from the magnetization of magnetic beads caused by the magnetic field generated by the sinusoidal AC current supplied to the transformer. FIG. 8B shows an illustrative embodiment of a graph illustrating the EMF output as a function of input current at the frequencies of 30, 60, and 90 kHz. As shown in the Figure, the EMF output has a linear response with the magnitude of the input current in this regime. The gap or difference between the EMF outputs of the transformers with and without beads becomes larger as the magnitude of the input current increases.

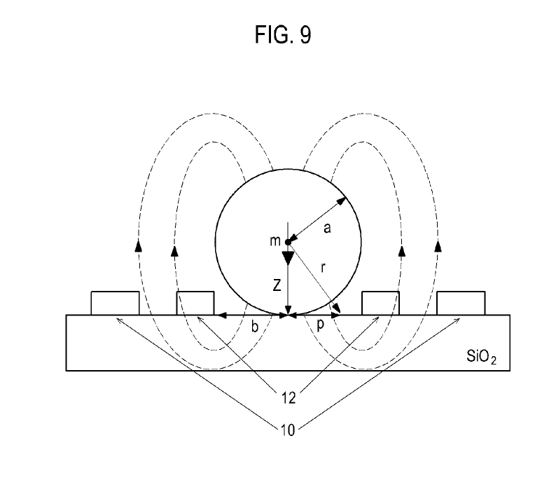

FIG. 9 shows a schematic diagram of an illustrative embodiment of a scenario where a magnetic bead is placed on the nanometer scale transformer. The nanometer scale transformer comprises two metal rings according to the one embodiment of the disclosure shown in FIG. 1. Assuming that a magnetic bead is uniformly magnetized, the magnetic field from the bead is given by

$$\begin{matrix}B = \frac{{μ}_{0}}{4 π} ( \frac{3 ( m \cdot r ) r}{{r}^{5}} - \frac{m}{{r}^{3}} ) \\ = \frac{{μ}_{0}}{4 π} ( \frac{3 mz}{{r}^{5}} {a}_{ρ} + \frac{m ( 2 {z}^{2} - {ρ}^{2} )}{{r}^{5}} {a}_{z} )\end{matrix} \qquad ( 2 )$$

where m is the magnetic moment of the bead, and r, ρ, and z are the radial, the horizontal, and the normal distance from the center of the magnetic bead, respectively. In view of the coordinate system shown in FIG. 9, the magnetic field is a combination of horizontal (ρ) and normal (z) components relative to the surface of the nanometer scale transformer. However, only the normal component is effective for EMF outputs, because only the magnetic field perpendicularly passing through the coupling area is valid in Faraday's law. Then further assuming that a magnetized magnetic bead is centered on top of the nanometer scale transformer, the magnetic flux (Φ) due to the bead through the coupling area at a time can be calculated by integrating the flux over the area and given by

$$Φ = \frac{{μ}_{0}}{2} \frac{{b}^{2}}{{( {a}^{2} + {b}^{2} )}^{3 / 2}} m \qquad ( 3 )$$

where a and b are the radii of the bead and the coupling area, respectively.

Under the above scenario, the simulation was performed using the previous electromagnetic field simulator. The magnetic field pattern from the transformer without the beads was first calculated when the input current of 10 mA with 90 kHz is supplied to the outer ring. In this case, the magnetic flux through the inner ring was extracted by integrating the magnetic field over the inner area of the inner ring and the value was 6.17 fWb (10⁻¹⁵ weber). This value linearly corresponds to the average output voltage of 124.2 μV as shown in FIGS. 8(a) and 8(b). Then, we estimated the magnetic flux from the bead using an equation (3) under the scenario. The simulated magnetic field caused by the input AC current was 4.1 mT (10⁻³ tesla) at the center of the bead and the estimated magnetic flux from the magnetized bead was 0.73 fWb. Assuming that the nanometer scale transformer has a linear response to the magnetic flux passing through the inner ring of the transformer, the expected average EMF output increase due to the bead will be 14.7 μV. In the above-explained experiments, the actual increase of the average output response (the difference of the EMF outputs from the transformers between with and without magnetic beads) was 11.4 μV as shown in FIGS. 8(a) and 8(b). The estimated value is somewhat larger than the actual experimental value. This may be due to the assumption that the magnetic bead is uniformly magnetized and that the bead is placed at the center of the nano-transformer. Actually, the magnetic field around the beads is not uniform, and the beads are not exactly centered on the transformer in reality as shown in FIG. 5. However, the estimated value is comparable to the experimental result, and this implies that the magnetic field from the outer ring of the transformer effectively magnetizes the beads and that the field from the beads has a sufficient influence on the EMF outputs of the nanometer scale transformer to detect the presence of the magnetic beads.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An nanometer scale transformer comprising:
a first circuit;
a second circuit; and
a coupling area configured for magnetic induction coupling between said first circuit and said second circuit.

2. The nanometer scale transformer of claim 1, further comprising a substrate of SiO₂, and wherein said first and said second circuits and said coupling area are fabricated on said substrate.

3. The nanometer scale transformer of claim 1, wherein said first and said second circuits are made of metals comprising Ti, Au, and combination thereof

4. The nanometer scale transformer of claim 1, wherein each of said first and said second circuits is substantially in the shape of the ring, and said each ring has different radius and width.

5. The nanometer scale transformer of claim 4, wherein said ring for said first circuit has approximately a 300 nm radius and approximately a 100 nm width, or has approximately a 700 nm radius and approximately a 200 nm width.

6. The nanometer scale transformer of claim 4, wherein said ring for said second circuit has approximately a 700 nm radius and approximately a 200 nm width, or has approximately a 1400 nm radius and approximately a 500 nm width.

7. The nanometer scale transformer of claim 4, wherein said rings for said first and said second circuits are substantially concentric.

8. The nanometer scale transformer of claim 4, wherein said coupling area is inside one of said rings of said first and said second circuits

9. The nanometer scale transformer of claim 4, wherein said first and said second circuits are comprised of two metal rings and a DC current of 10 mA is supplied to the outer ring via a terminal pair connected to the outer ring.

10. The nanometer scale transformer of claim 1, wherein each of said first and said second circuits is substantially in the shape of one of: the oval, the triangle, the rectangle, the polygon or the square.

11. The nanometer scale transformer of claim 1, further comprising a first terminal pair connected to said first circuit and/or a second terminal pair connected to said second circuit.

12. The nanometer scale transformer of claim 11, further comprising an amplifier connected to one of said first and second terminal pairs.

13. The nanometer scale transformer of claim 1, further comprising a first and second terminal pair fabricated on a substrate with Au wires and terminated with a contact pad.

14. A micro array comprising:
a solid platform;
a plurality of spots on said solid platform; and
a plurality of nanometer scale transformers, each transformer being fabricated in each of said spots.

15. The micro array of claim 14, wherein said nanometer scale transformer comprises a first circuit, a second circuit, and a coupling area configured for magnetic induction coupling between said first circuit and said second circuit.

16. The micro array of claim 15, wherein each of said first and said second circuits is substantially in the shape of the ring, and said each ring has a different radius and width.

17. A method of manipulating a magnetic carrier comprising:
supplying a DC current to a nanometer scale transformer; and
allowing a magnetic field from said nanometer scale transformer to act upon said the magnetic carrier, wherein said nanometer scale transformer comprises a first circuit, a second circuit, and a coupling area configured for magnetic induction coupling between said first circuit and said second circuit.

18. The method according to claim 17, wherein each of said first and said second circuits is substantially in the shape of the ring, and said each ring has a different radius and width.

19. The method according to claim 17, wherein said nanometer scale transformer further comprises a first terminal pair connected to said first circuit or a second terminal pair connected to said second circuit.

20. The method according to claim 19, wherein said DC current is supplied via one of said first and second terminal pairs.

21. A method of detecting a magnetic carrier comprising:
supplying an AC current to a nanometer scale transformer; and
measuring an electromotive force (EMF) output from said nanometer scale transformer, wherein said nanometer scale transformer comprises a first circuit, a second circuit, and a coupling area configured for magnetic induction coupling between said first circuit and said second circuit.

22. The method according to claim 21, wherein said EMF output is increased when said magnetic carrier is on said nanometer scale transformer.

23. The method according to claim 21, wherein said EMF output is increased in accordance with a magnitude or frequency of said AC current.

24. The method according to claim 21, wherein each of said first and said second circuits is substantially in the shape of the ring, and said each ring has a different radius and width.

25. The method according to claim 21, wherein said nanometer scale transformer further comprises a first terminal pair connected to said first circuit or a second terminal pair connected to said second circuit.

26. The method according to claim 25, wherein said AC current is supplied via one of said first and second terminal pairs, and wherein said EMF output is measured via one of said first and second terminal pairs.

27. The method according to claim 25, wherein a lock-in amplifier is connected to one of said first and second terminal pairs, and said EMF output is measured through said lock-in amplifier.

28. The method according to claim 30, wherein said magnetic carrier around said coupling area is magnetized by a magnetic field generated by said AC current.
